(19) United States
(12) Patent Application Publication
(10) Pub. No.: US 2006/0181313 A1
(43) Pub. Date: Aug. 17, 2006

(54) Transistor logic circuit

(76) Inventor: Akira Akahori, Tokyo (JP)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/269,610

(22) Filed: Nov. 9, 2005

(30) Foreign Application Priority Data
Feb. 15, 2005 (JP) 037065/2005

(51) Int. Cl. H03K 19/094

(52) U.S. Cl. 326/113

(57) ABSTRACT

An input inverter section inverts a plurality of input signals to generate complementary signals and supplies signals complementary to these input signals to a logic circuit network. The logic circuit network comprises a plurality of pairs of depletion type NMOSs (NDMOSs) whose conducting states are respectively controlled on a complementary basis by the supplied signals. Since each of the NDMOSs has a threshold voltage set negative, a drain current flows even if its gate voltage is 0V, and hence it is not brought into a complete off state. It is therefore possible to speed up a change from an off state to an on state and raise a signal of an “H” level at a node from which a signal indicative of the result of logical operations is outputted, to a potential identical to a power supply potential. The signal at the node is outputted from an output buffer section as an output signal.

### FIELD OF THE INVENTION

The present invention relates to a transistor logic circuit.

### BACKGROUND OF THE INVENTION

As techniques related to transistor logic circuits, the following have been disclosed in a patent document 1 (Japanese Patent Application No. 34074/2004) and a non-patent document 1 (M. Muntearu et al, “Singled Ended Pass-Transistor Logic for Low Power Design”, ASILOMAR Conference on Signals, Systems and Computer, Monterey Calif., Oct. 24-27. 1999).

With the progress of high integration of an LSI and improvements in its performance, there has been a strong technical demand for a reduction in power consumption and speeding-up. Since the power consumption is proportional to the square of a power supply voltage in a CMOSLSI, a reduction in the power supply voltage is a means most effective for the reduction in power consumption. However, the reduction in the power supply voltage leads to a reduction in operating speed of the CMOSLSI. Thus, the subsequent improvement in the performance of the LSI needs a circuit design method for maintaining the operating speed while ensuring a reduction in the voltage of a transistor and a reduction in the power supply voltage. A Single Ended Pass-Transistor Logic (hereinafter called “SPL”) has been proposed as one circuit design method for maintaining an operating speed while ensuring a reduction in power supply voltage.

The SPL comprises an input inverter section, a logic circuit network using N channel MOS transistors (hereinafter called “NMOSs”), and an output buffer-section which converts a signal outputted from the logic circuit network to a logical level corresponding to a power supply potential VDD and outputs it therefrom. The above non-patent document 1 discloses detailed explanations of SPL based on bulk MOSs that constitute MOS transistors using a normal silicon substrate.

FIG. 2 is a configuration diagram of a carry circuit based on the conventional SPL illustrated in the above non-patent document 1.

The input inverter section has three inverters which invert input signals A, B, and C and outputs inverted signals /A, /B, and /C (where “/” means the inverse of each signal). The input inverter section generates complementary set signals that consist of the input signals and their inverted signals.

The logic circuit network generates logic signals corresponding to the input signals A, B, and C and outputs them to a node N. The logic circuit network comprises a plurality of pairs of NMOSs whose conducting states are controlled by their corresponding complementary signals B and /B, and C and /C. The logic circuit network constituted of the paired NMOSs is configured in such a manner that a signal obtained in accordance with predetermined logic is outputted to the node N through each of paths formed by the NMOSs controlled to an on state according to the signals A, /A, B, /B, C, and /C.

The output buffer section inverts the signal obtained at the node N and outputs an output signal OUT having a predetermined logical level of “H” or “L”. The output buffer section comprises an inverter whose input side is connected to the node N, and a P channel MOS transistor (hereinafter called “PMOS”) connected between the node N and the power supply potential VDD and on-off controlled by the output signal of the inverter.

In the SPL, the input signals A, B, and C are inverted by the input inverter section to produce their inverted signals /A, /B, and /C, which in turn are supplied to their corresponding gates of the NMOSs of the logic circuit network as paired complementary signals. Thus, the NMOSs of the logic circuit network are switched to on or off according to the input signals, so that a discharge path to a ground potential GND is formed with respect to the node N, or a charge path to the power supply potential VDD is formed with respect to the node N. And the result of logical operations is outputted to the node N. The signal at the node N is inverted by the inverter of the output buffer section, which in turn is outputted as the output signal OUT.

Thus, in the logic circuit network, the discharge path or the charge path with respect to the node N is formed in accordance with changes in threshold voltages Vtn (e.g., about 0.2V) of the NMOSs with respect to the input voltages. Therefore, the logic circuit network is capable of performing a high-speed operation as compared with a CMOS logic circuit in which ½ of the power supply potential VDD is set as a logic threshold voltage. This means that the SPL can provide a reduction in operating voltage and a high-speed operation as compared with the CMOS logic circuit in which the logic threshold voltage exists.

However, the SPL has the following problems.

In the logic circuit network in FIG. 2, for example, each of the NMOSs connected to the node N has a drain as its input side and a source as its output side (i.e., node N side). The signal C (or /C) is supplied to its gate. A drain current flows from the drain to the source. A gate-to-source voltage Vgs corresponds to a voltage applied between the gate and source. Immediately after a change in gate voltage, the gate-to-source voltage results in Vgs=VDD (power supply voltage). When a charge current flows from the input side to the node N, an unillustrated load capacitance connected between the node N and ground potential GND is charged so that the potential at the node N rises. With its rise, the gate-to-source voltage Vgs decreases.

When the gate-to-source voltage Vgs decreases, the charge current decreases and hence a charging speed is reduced. Further, when the potential at the node N rises to VDD-Vtn, the gate voltage of each NMOS results in Vgs Vtn. Thus, the NMOS is brought into an off state and hence no current flows subsequently. Accordingly, the potential at the node N rises only to VDD-Vtn at maximum.

The output buffer section in FIG. 2 is provided to generate, outside, an output signal OUT of a normal logic level (i.e., power supply potential VDD or ground potential GND). When the level of the node N rises to VDD-Vtn in the output buffer section, the output signal of the inverter is brought to “L” so that the PMOS is brought into an on state. Consequently, the charge path with respect to the node N is formed through the PMOSs as viewed from the power supply potential VDD. Thus, the PMOS is switched using the output signal of the inverter to thereby subserve or assist in the charging operation of the node N. However, a delay time produced by the inverter is needed to switch the PMOS. Therefore, the formation of the charge path at the node N is delayed by the delay time of the inverter, thus causing a problem that speeding-up is restricted.

### SUMMARY OF THE INVENTION

The present invention has been made in view of the foregoing. It is therefore an object of the present invention to make fast a charging operation at a node N to thereby speed up a transistor logic circuit.

According to one aspect of the present invention, for attaining the above object, there is provided a transistor logic circuit comprising a logic circuit network which comprises a plurality of pairs of transistors whose conducting states are respectively controlled on a complementary basis according to a plurality of input signals, and outputs a signal indicative of the result of logical operations on the input signals to an intermediate node; and an output buffer which inverts the signal at the intermediate node and outputs the same therefrom as an output signal, wherein the plurality of pairs of transistors of the logic circuit network are all constituted of depletion type NMOSs (hereinafter called “NDMOSs”). A plurality of input inverters which inverts the plurality of input signals to generate complementary input signals and supplies the generated input signals to the plurality of pairs of transistors as control signals, are provided. These logic circuit network, input inverters and output buffer are formed on an SOI (Silicon on Insulator) substrate.

The present invention brings about the advantages that since transistors that constitute a logic circuit network are formed of NDMOSs, the potential of an “H” level at an intermediate node can be raised to a power supply potential VDD, and speeding-up can be achieved as compared with the conventional SPL.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. 1 is a configuration diagram of a transistor logic circuit showing a first embodiment of the present invention;

FIG. 2 is a configuration diagram of a carry circuit based on a conventional SPL;

FIG. 3 is a characteristic diagram showing one example of an I-Vg characteristic of an NDMOS in FIG. 1;

FIG. 4 is a simulation waveform diagram showing one example of the operation of the transistor logic circuit shown in FIG. 1; and

FIG. 5 is a configuration diagram of a transistor logic circuit showing a second embodiment of the present invention.

### DETAILED DESCRIPTION OF THE PREFERRED EMBODIMENTS

A plurality of pairs of transistors in a logic circuit network are constituted of NDMOSs and depletion type PMOSs (hereinafter called “PDMOS”). The transistors may be configured in such a way as to complementarily control conducting states of NDMOSs and PDMOSs set as these pairs according to input signals.

The above and other objects and novel features of the present invention will become more completely apparent from the following descriptions of preferred embodiments when the same is read with reference to the accompanying drawings. The drawings, however, are for the purpose of illustration only and by no means limitative of the invention.

### First Preferred Embodiment

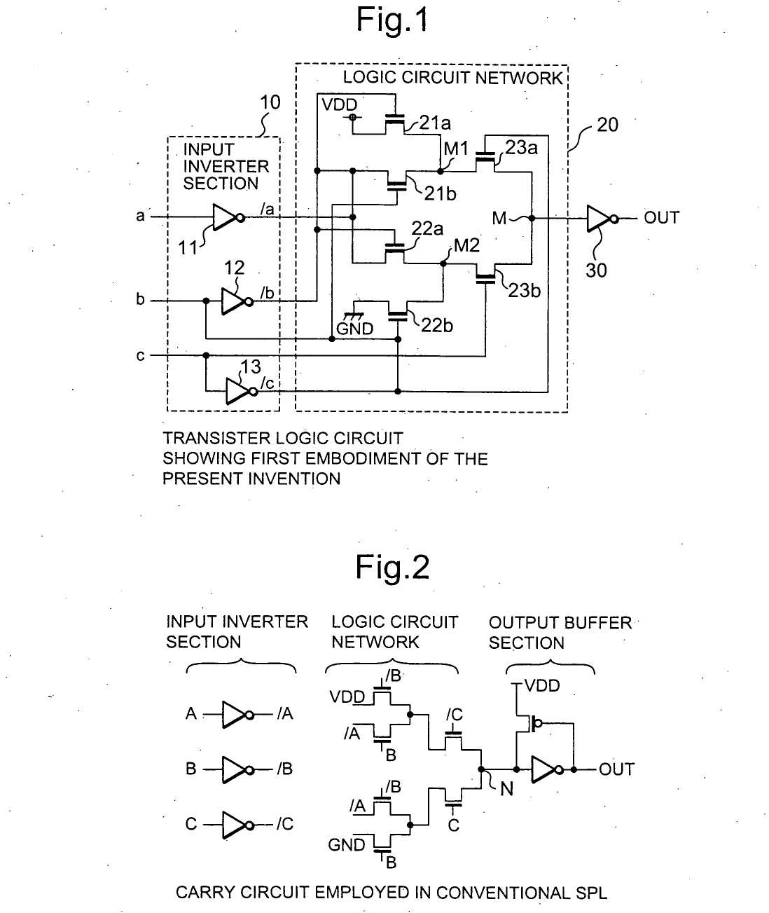

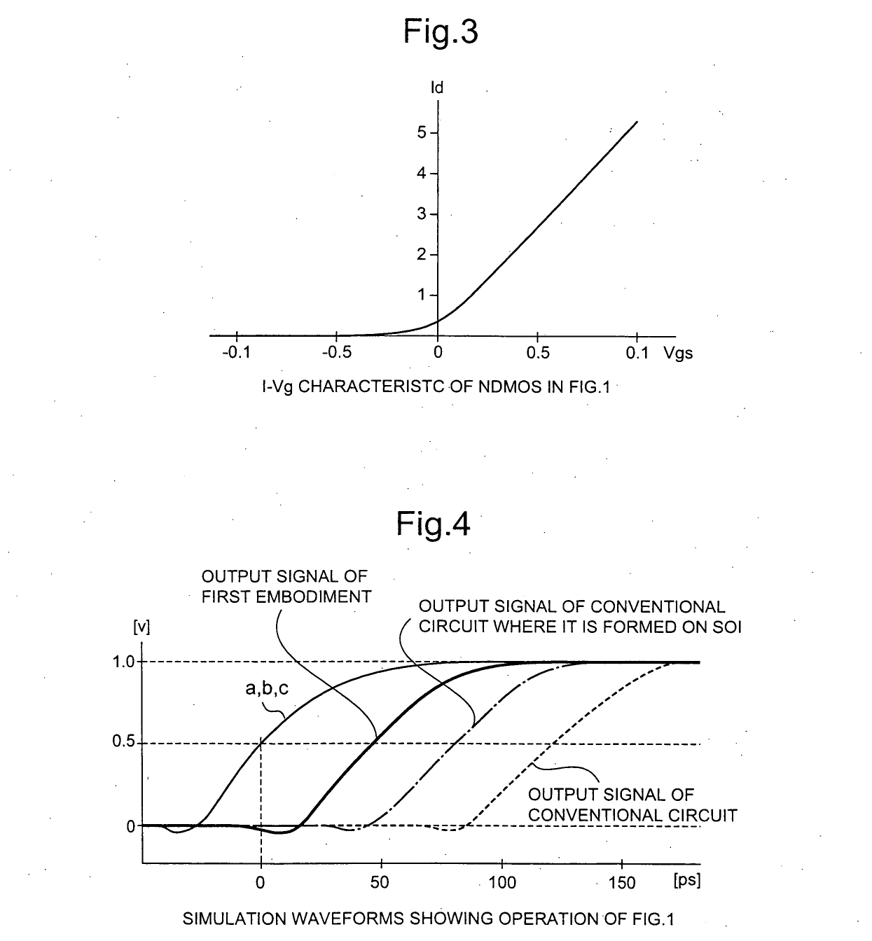

FIG. 1 is a configuration diagram of a transistor logic circuit showing a first embodiment of the present invention.

The transistor logic circuit is configured on an SOI substrate wherein a silicon thin film is formed on an insulated board such as silicon dioxide, sapphire, glass or the like. The transistor logic circuit performs a logical operation similar to that shown in FIG. 2 and includes an input inverter section 10, a logic circuit network 20 constituted of NDMOSs, and an output buffer section 30 which converts a signal outputted from the logic circuit network 20 to a logical level corresponding to a power supply potential VDD and outputs it therefrom.

The input inverter section 10 has inverters 11, 12, and 13 which invert input signals a, b, and c and output complementary signals /a, /b, and /c, respectively. These inverters 11, 12, and 13 are formed of normal CMOSs in the same manner as conventional. The input signals b and c, and the signals /a, /b, and /c generated at the input inverter section 10 are to be supplied to the logic circuit network 20. The logic circuit network 20 comprises a plurality of pairs of NDMOSs whose conducting states are controlled by the complementary signals based on the input signals a, b, and c and which form a charge path between a node M corresponding to an intermediate node and the power supply potential VDD, or a discharge path between the node M and a ground potential GND. That is, the logic circuit network 20 outputs a signal indicative of the result of logical operations on the input signals a, b, and c to the node M and is constituted of NDMOSs 21a and 21b, NDMOSs 22a and 22b, and NDMOSs 23a and 23b configured in pairs respectively.

The NDMOS 21a is provided between the power supply potential VDD and a node M1 and configured in such a manner that its conducting state is controlled by the signal /b. The NDMOS 21b is provided between the signal /a and the node M1 and configured such that its conducting state is controlled by the signal b. The NDMOS 22a is provided between the signal /a and a node M2 and configured in such a manner that a conducting state thereof is controlled by the signal /b. The NDMOS 22b is provided between the ground potential GND and the node M2 and configured such that its conducting state is controlled by the signal b. Further, the NDMOS 23a is provided between the node M1 and the node M and configured in such a manner that its conducting state is controlled by the signal /c. The NDMOS 23b is provided between the node M2 and the node M and configured such that its conducting state is controlled by the signal c.

The output buffer section 30 inverts a logical level at the node M and outputs an output signal OUT and comprises a CMOS inverter similar to the input inverter section 10.

That is, the transistor logic network is equivalent to one in which the circuits shown in FIG. 2 are formed on the SOI substrate and the NMOSs of the logic circuit network in FIG. 2 are all substituted with NDMOSs. Each of the NDMOSs is a transistor configured in such a manner that with implantation of ions into the gate region of the NMOS, it is not brought into a complete off state even though its gate-to-source voltage Vgs reaches 0V, and a slight drain current flows therethrough. However, the drain current (i.e., through current) at the time that the gate-to-source voltage Vgs is 0V, is restricted to such an extent that no problem occurs in the logical operation.

FIG. 3 is a characteristic diagram showing one example of an I-Vg characteristic of the NDMOS in FIG. 1. The horizontal axis indicates the gate-to-source voltage Vgs, and the vertical axis indicates the drain current Id.

The NDMOS is one formed on the SOI substrate with a gate length thereof and a gate width thereof as 0.15 μm and 10 μm respectively. FIG. 3 shows the drain current Id at the time that 1V is applied between the source and drain to change the gate-to-source voltage Vgs from −1V to +1V. As is apparent from FIG. 3, the gate-to-source voltage Vgs at the time that the drain current Id reaches approximately 0, i.e., a threshold voltage Vtn reaches about −0.2V. Even when the gate-to-source voltage Vgs is 0V, the drain current Id flows and the NDMOS is not brought into the complete off state. Incidentally, the magnitudes of the threshold voltage Vtn and the through current can be controlled by the amount of implantation of ions into the gate region.

The operation of the transistor logic circuit will next be explained.

Input signals a, b, and c supplied from outside are respectively inverted by the inverters 11, 12, and 13 of the input inverter section 10, so that signals /a, /b, and /c complementary to the input signals a, b, and c are generated and supplied to the logic circuit network 20.

Since the logic circuit network 20 consists entirely of the NDMOSs, the NDMOSs whose gates are supplied with a logic signal of “H” are respectively brought into an on state. On the other hand, the NDMOSs whose gates are supplied with a logic signal of “L” are not brought into a complete off state respectively, and hence slight drain currents flow. However, the on resistance of each NDMOS placed in the on state is extremely smaller than that of each NDMOS placed in the incomplete off state. Thus, the NDMOSs placed in the on state constitute the charge path between the node M and the power supply potential VDD or the discharge path between the node M and the ground potential GND.

When the input signals a, b, and c are all “L”, for example, the NDMOSs 21a, 22a, and 23a are respectively brought into an on state, and the NDMOSs 21b, 22b, and 23b are respectively brought into an incomplete off state. Thus, the charge path is configured between the power potential VDD and the node M through the NDMOSs 21a and 23a. Since the threshold voltages Vtn of the NDMOSs 21a and 23a are −0.2V, the potential of the node M results in the power supply potential VDD. Accordingly, the PMOSs used to raise the potential of the node N to the power supply potential VDD in FIG. 2 become unnecessary in the present transistor logic circuit. The signal at the node M is inverted by the inverter of the output buffer section 30 from which an output signal OUT of “L” is outputted.

Next, when the input signals a, b, and c change into “H”, for instance, the NDMOSs 21a, 22a, and 23a are respectively brought into an incomplete off state, and the NDMOSs 21b, 22b, and 23b placed in the incomplete off state up to now are respectively brought into an on state. Since the NDMOSs 21b, 22b, and 23b are not placed in a complete cutoff state respectively and the slight drain current has flowed, the change of the NDMOSs to the on state is performed rapidly. Thus, the discharge path is formed between the ground potential GND and the node M through the NDMOSs 22b and 23b, and the potential of the node M results in the ground potential GND. The signal at the node M is inverted by the inverter of the output buffer section 30 from which an output signal OUT of “H” is outputted.

FIG. 4 is a simulation waveform diagram showing one example of the operation of FIG. 1.

In the present simulation, the waveform of an output signal OUT at the time that the power supply potential VDD is set to 1V and the input signals a, b, and c are simultaneously changed from “L” to “H” is indicated by a solid line. A signal outputted from the conventional circuit (where the threshold voltage of the NMOS is assumed to be 0.3V) shown in FIG. 2 is indicated by a broken line in FIG. 4 for comparison. Further, an output signal obtained when the conventional circuit (where the threshold voltage of the NMOS is assumed to be 0.2V) is formed on its corresponding SOI substrate, is indicated by a dashed line.

Examining the time (i.e., delay time) from the time when the input signals change from “L” to “H” (that is, the input signals are brought to VDD/2) to the time when the output signal changes from “L” to “H” (that is, the output signal is brought to VDD/2) from the simulation result, the time was found to be 47 ps in the circuit according to the first embodiment, the time was found to be 120 ps in the conventional circuit, and the time was found to be 85 ps in the conventional circuit formed on the SOI substrate.

As described above, the transistor logic circuit according to the first embodiment has the advantages that since the transistors that constitute the logic circuit network 20 are all formed by the NDMOSs, a response speed becomes fast, and the potential of the “H” level at the node M can be raised to the power supply potential VDD, whereby the transistor logic circuit can be rendered fast as compared with the conventional SPL. Further, since the transistor logic circuit is formed on the SOI substrate, a subthreshold coefficient becomes large and the through current can be reduced. Thus, the transistor logic circuit has the advantage in that the speeding up thereof is possible with the small through current. Incidentally, when the transistor logic circuit of the present invention is formed of bulk MOSs, there are problems that, for example, the through current increases, and the complete device isolation becomes difficult so that a variation in threshold value due to a latchup effect occurs. The present technique encounters difficulties in configuring a transistor logic circuit having desired characteristics.

Although the first embodiment has illustrated the carry circuit as the logic circuit network 20 by way of example, any logic circuit is applicable if circuits are adopted which use, as plural pairs, paired NDMOSs whose conducting states are complementarily controlled by input signals, and which are capable of constituting a charge path between the node M on the output side and the power supply potential VDD, and a discharge path between the node M and the ground potential GND.

Although the power supply voltage VDD is set to 1V, and the threshold voltage of each NDMOS is set to −0.2V in the first embodiment, the threshold voltage can be reduced from about (−0.3×VDD) to about (−0.4×VDD) depending upon circuits to be configured.

### Second Preferred Embodiment

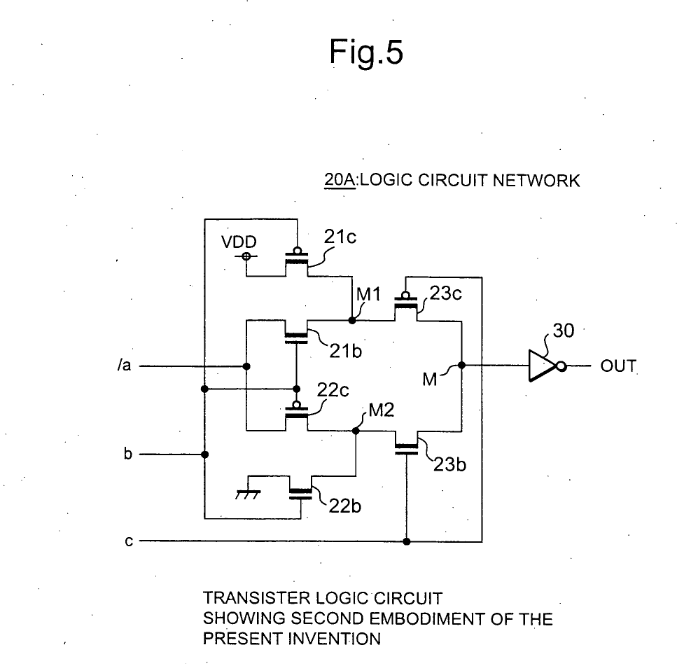

FIG. 5 is a configuration diagram of a transistor logic circuit showing a second embodiment of the present invention. Constituent elements common to those shown in FIG. 1 are given the common reference numerals respectively.

The transistor logic circuit is configured on an SOI substrate in a similar to FIG. 1 and performs a logical operation similar to FIG. 1. The transistor logic circuit does not include the input inverter section 10 shown in FIG. 1 but has a logic circuit network 20A constituted of NDMOSs and PDMOSs, and an output buffer section 30 similar to FIG. 1.

In a manner similar to the NDMOSs, each of the PDMOSs is a transistor configured in such a manner that with implantation of ions into the gate region of the PMOS, it is not brought into a complete off state even though its gate-to-source voltage Vgs reaches 0V, and a slight drain current flows therethrough. However, the drain current (i.e., through current) at the time that the gate-to-source voltage Vgs is 0V, is restricted to such an extent that no problem occurs in the logical operation.

The logic circuit network 20A comprises an NDMOS 21b and a PDMOS 21c, an NDMOS 22b and a PDMOS 22c, and an NDMOS 23b and a PDMOS 23c, which are respectively configured in pairs.

The PDMOS 21c is provided between a power supply potential VDD and a node M1, and the NDMOS 21b is provided between an input signal /a and the node M1, respectively. Conducting states of the PDMOS 21c and the NDMOS 21b are complementarily controlled according to a common input signal b. The PDMOS 22c is provided between the input signal /a and a node M2, and the NDMOS 22b is provided between a ground potential GND and the node M2, respectively. Conducting states of the PDMOS 22c and the NDMOS 22b are complementarily controlled according to the common input signal b. Further, the PDMOS 23c is provided between the node M1 and a node M, and the NDMOS 23b is provided between the node M2 and the node M, respectively. Conducting states of the PDMOS 23c and the NDMOS 23b are complementarily controlled according to a common input signal c.

The transistor logic circuit is similar to FIG. 1 in operation except that the input signals a, b, and c are supplied to the logic circuit network 20A constituted of the complementary PDMOSs and NDMOSs in place of the fact that the input signals a, b, and c are inverted to generate the complementary signals /a, /b, and /c and the generated signals are supplied to the NDMOSs of the logic circuit network 20.

Thus, since the transistor logic circuit has the advantages that since the transistors that constitute the logic circuit network 20A are all formed by the DMOSs, a response speed becomes fast in a manner similar to FIG. 1, and the potential of the “H” level at the node M can be raised to the power supply potential VDD, whereby the transistor logic circuit can be speeded up as compared with the conventional SPL. Further, since the transistor logic circuit is formed on the SOI substrate in a manner similar to FIG. 1, a subthreshold coefficient becomes large and the through current can be reduced. Thus, the transistor logic circuit has the advantage in that the speeding up thereof is possible with the small through current. Incidentally, when the transistor logic circuit of the present invention is formed of bulk MOSs, there are problems that, for example, the through current increases, and the complete device isolation becomes difficult so that a variation in threshold value due to a latchup effect occurs. The present technique encounters difficulties in configuring a transistor logic circuit having desired characteristics.

Further, the transistor logic circuit has the advantages that since the transistor logic circuit does not need the input inverter section, it can be simplified in circuit configuration, and since the time required to generate the complementary signals /b and /c becomes unnecessary, its operating speed becomes fast by a delay time (6 ps according to simulation) produced by the inverter.

Incidentally, although the threshold voltages of the NDMOS and PDMOS differ according to circuits to be constituted, the threshold voltage can be set to (−0.2×VDD) to (−0.3×VDD) in the case of the NDMOS, whereas the threshold voltage can be set to about (0.2×VDD) to about (0.3×VDD) in the case of the PDMOS.

While the preferred forms of the present invention have been described, it is to be understood that modifications will be apparent to those skilled in the art without departing from the spirit of the invention. The scope of the invention is to be determined solely by the following claims.

What is claimed is:

1. A transistor logic circuit comprising:
a logic circuit network which comprises a plurality of pairs of transistors whose conducting states are respectively controlled on a complementary basis according to a plurality of input signals, and outputs a signal indicative of the result of logical operations on the input signals to an intermediate node;
an output buffer which inverts the signal at the intermediate node and outputs the same therefrom as an output signal;
depletion type N channel MOS transistors constituting all of said plurality of pairs of transistors of said logic circuit network; and
a plurality of input inverters which inverts the plurality of input signals to generate complementary input signals and supplies the generated input signals to said plurality of pairs of transistors as control signals,
wherein said logic circuit network, said input inverters and said output buffer are formed on an SOI substrate.

2. A transistor logic circuit comprising:
a logic circuit network which comprises a plurality of pairs of transistors whose conducting states are respectively controlled on a complementary basis according to a plurality of input signals, and outputs a signal indicative of the result of logical operations on the input signals to an intermediate node; and
an output buffer which inverts the signal at the intermediate node and outputs the same therefrom as an output signal,
wherein said plurality of pairs of transistors of said logic circuit network are constituted of depletion type N channel MOS transistors, and depletion type P channel MOS transistors, and
wherein said logic circuit network and said output buffer are formed on an SOI substrate.
